(19) United States
(12) Patent Application Publication
(10) Pub. No.: US 2026/0128078 A1
(43) Pub. Date: May 7, 2026

(54) SEMICONDUCTOR DEVICE HAVING INPUT BUFFER CIRCUIT

(71) Applicant: MICRON TECHNOLOGY, INC., Boise, ID (US)

(72) Inventor: Shun Nishimura, Sagamihara (JP)

(73) Assignee: MICRON TECHNOLOGY, INC., Boise, ID (US)

(21) Appl. No.: 19/340,676

(22) Filed: Sep. 25, 2025

Related U.S. Application Data
(60) Provisional application No. 63/715,226, filed on Nov. 1, 2024.

(51) Int. Cl. G11C 11/4076

(52) U.S. Cl. CPC G11C 11/4076

(57) ABSTRACT

An example apparatus includes: a differential amplifier circuit having a pair of first and second input transistors, the first input transistor having a control electrode supplied with an input signal, the second input transistor having a control electrode supplied with a reference potential; and a replica circuit having first, second, and third replica transistors coupled in series. The differential amplifier circuit is configured to be activated responsive to a first timing signal. The first and second input transistors and the first and second replica transistors have a first conductivity type. The third replica transistor has a second conductivity type opposite. Each of the first and third replica transistors has a control electrode supplied with the second timing signal. The second replica transistor has a control electrode supplied with the reference potential.

### CROSS-REFERENCE TO RELATED APPLICATIONS

This application claims the filing benefit of U.S. Provisional Application No. 63/715,226, filed Nov. 1, 2024. This application is incorporated by reference herein in its entirety and for all purposes.

### BACKGROUND

Semiconductor devices such as a DRAM may have a write oscillator circuit that monitors the time period from when a data strobe signal is input from the outside until the write data is latched in the input buffer circuit. It is desirable that the time period measured using the write oscillator circuit reflects as accurately as possible the time from when a data strobe signal is actually input from the outside until the write data is actually latched in the input buffer.

### BRIEF DESCRIPTION OF THE DRAWINGS

FIG. 1 is a block diagram showing a configuration of a semiconductor memory device according to an embodiment of the present disclosure;

FIG. 2 is a block diagram showing a configuration of main components of a data control circuit;

FIG. 3 is a circuit diagram of a data latch circuit;

FIG. 4 is a block diagram showing a configuration of a write oscillator circuit.

FIG. 5 is a circuit diagram of a DQIB replica circuit; and

FIG. 6 is a timing diagram for explaining the function of the write oscillator circuit.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

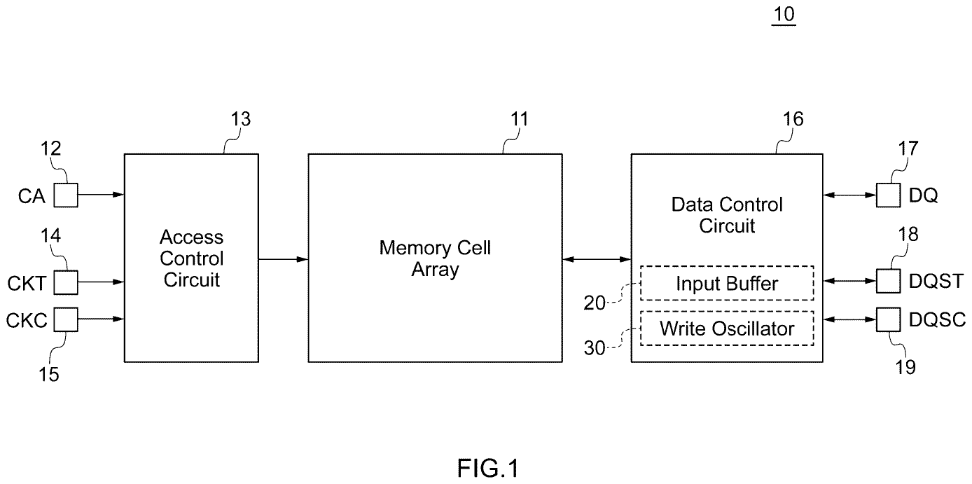

FIG. 1 is a block diagram showing a configuration of a semiconductor memory device 10 according to an embodiment of the present disclosure. The semiconductor memory device 10 shown in FIG. 1 is an LPDDR5 DRAM and includes a memory cell array 11. When access is made to the memory cell array 11, a command address signal CA is input to a command address terminal 12 from outside. The command address signal CA is supplied to an access control circuit 13. The access control circuit 13 synchronizes with complementary clock signals CKT and CKC respectively input to clock terminals 14 and 15, thereby decoding the command address signal CA, counting latencies, and the like.

When a command included in the command address signal CA indicates a read operation, the access control circuit 13 makes read-access to a memory cell included in the memory cell array 11 based on an address included in the command address signal CA. Read data DQ read from the accessed memory cell is output to outside from a data I/O terminal 17 via a data control circuit 16. When the command included in the command address signal CA indicates a write operation, write data DQ input to the data I/O terminal 17 is transferred to the memory cell array 11 via an input buffer circuit 20 included in the data control circuit 16. The write data DQ is input to the memory cell array 11 as it synchronizes with complementary data strobe signals DQST and DQSC respectively supplied to data strobe terminals 18 and 19. The write data DQ having been transferred to the memory cell array 11 is written in the memory cell included in the memory cell array 11 based on the address included in the command address signal CA.

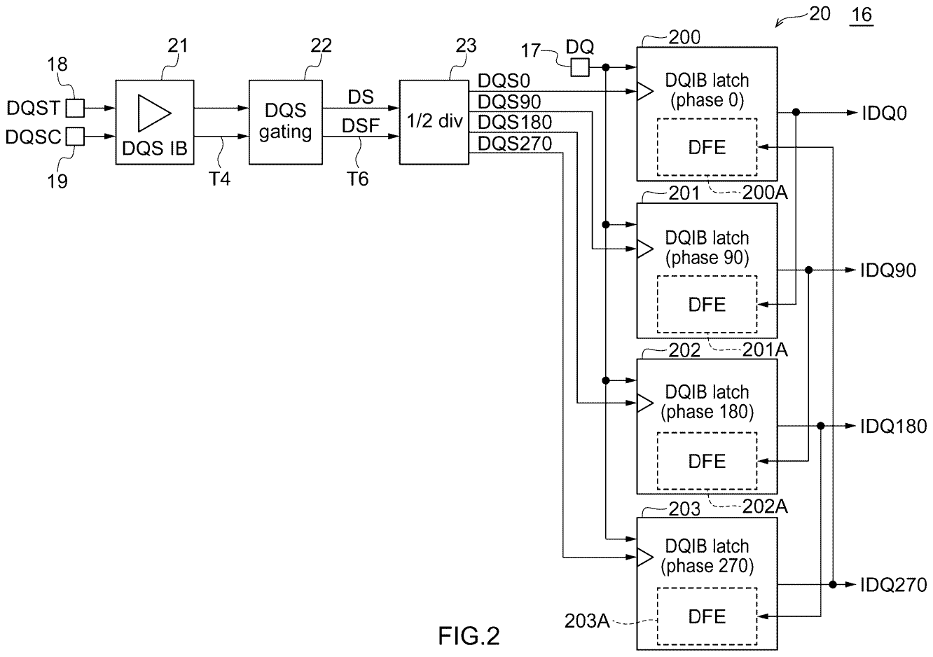

FIG. 2 is a block diagram showing a configuration of main components of the data control circuit 16. As shown in FIG. 2, the data control circuit 16 includes a gating circuit 22 that receives data strobe signals DQST and DQSC via an input buffer 21. The data strobe signals DQST and DQSC buffered by the input buffer 21 constitute a timing signal T4. Internal data strobe signals DS and DSF output from the gating circuit 22 respectively correspond to the data strobe signals DQST and DQSC. The internal data strobe signals DS and DSF constitute the timing signal T6. The internal data strobe signals DS and DSF are input to a dividing circuit 23. The dividing circuit 23 generates four-phase internal data strobe signals DQS0, DQS90, DQS180, and DQS270 by dividing the internal data strobe signals DS and DSF. When the phase of the internal data strobe signal DQS0 is 0°, the phases of the internal data strobe signals DQS90, DQS180, and DQS270 are 90°, 180°, and 270°, respectively. The internal data strobe signals DQS0, DQS90, DQS180, and DQS270 are supplied to the input buffer 20.

The input buffer 20 includes a data latch circuit 200 that synchronizes with the internal data strobe signal DQS0 to latch the write data DQ, a data latch circuit 201 that synchronizes with the internal data strobe signal DQS90 to latch the write data DQ, a data latch circuit 202 that synchronizes with the internal data strobe signal DQS180 to latch the write data DQ, and a data latch circuit 203 that synchronizes with the internal data strobe signal DQS270 to latch the write data DQ. Write data IDQ0, write data IDQ90, write data IDQ180, and write data IDQ270 respectively latched on the data latch circuits 200 to 203 are transferred to the memory cell array 11.

The data latch circuits 200, 201, 202, and 203 respectively include a DFE (Decision Feedback Equalizer) circuit 200A, a DFE circuit 201A, a DFE circuit 202A, and a DFE circuit 203A each of which reduces ISI (Intersymbol Interference) noise. Data latched on the data latch circuit 200 is fed back to the DFE circuit 201A included in the data latch circuit 201. Data latched on the data latch circuit 201 is fed back to the DFE circuit 202A included in the data latch circuit 202. Data latched on the data latch circuit 202 is fed back to the DFE circuit 203A included in the data latch circuit 203. Data latched on the data latch circuit 203 is fed back to the DFE circuit 200A included in the data latch circuit 200.

In this manner, four data latch circuits 200 to 203 are allocated to one data I/O terminal 17. While only one data I/O terminal 17 is shown in FIGS. 1 and 2, a plurality (eight, for example) of data I/O terminals 17 are provided in practice, and four data latch circuits 200 to 203 are allocated to each of the data I/O terminals 17.

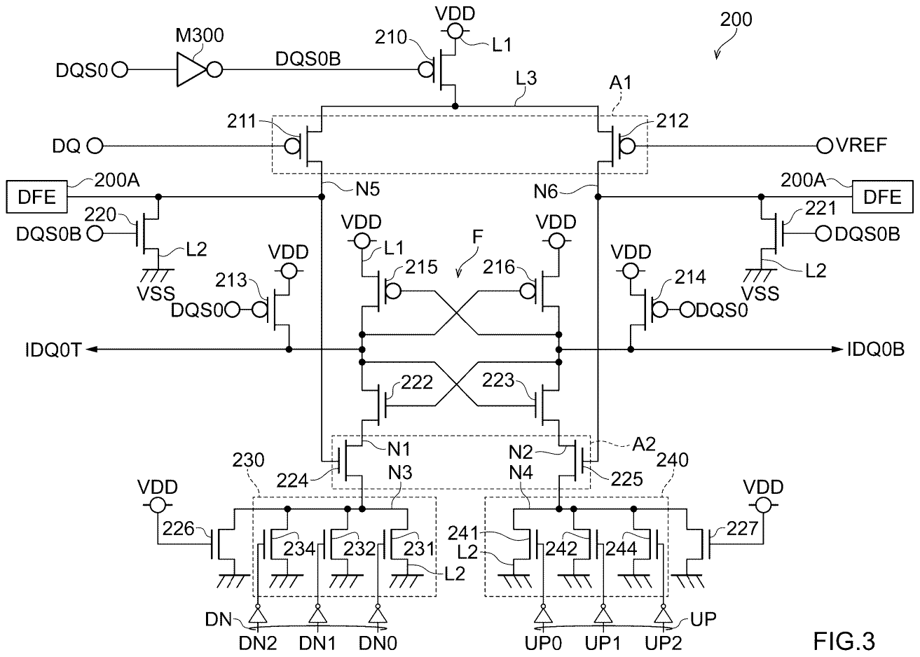

FIG. 3 is a circuit diagram of the data latch circuit 200. As shown in FIG. 3, the data latch circuit 200 includes P-channel MOS transistors 210 to 216, N-channel MOS transistors 220 to 227, and current control circuits 230 and 240. The transistor 210 is coupled between a power line L1 supplied with a power potential VDD and a common source line L3. An inversion signal DQS0B obtained by inverting the internal data strobe signal DQS0 by an inverter M300 is input to a gate electrode of the transistor 210. The transistor 211 is coupled between the common source line L3 and a circuit node N5. The write data DQ is input from outside to a gate electrode of the transistor 211 via the data I/O terminal 17. The transistor 212 is coupled between the common source line L3 and a circuit node N6. A reference potential VREF is supplied to a gate electrode of the transistor 212. The level of the reference potential VREF is between the potential of the write data DQ indicating the first logic level and the potential of the write data DQ indicating the second logic level. The transistors 211 and 212 constitute a differential amplifier circuit A1 that controls the amount of current flowing into the circuit nodes N5 and N6 based on a potential difference between the reference potential VREF and the write data DQ. The differential amplifier circuit A1 is activated when the inversion signal DQS0B of the internal data strobe signal DQS0 becomes a low level. The transistor 220 is coupled between the circuit node N5 and a power line L2 supplied with a ground potential VSS. A transistor 221 is coupled between the circuit node N6 and the power line L2 supplied with the ground potential VSS. The inversion signal DQS0B of the internal data strobe signal DQS0 is input to gate electrodes of the transistors 220 and 221. With this configuration, when the inversion signal DQS0B of the internal data strobe signal DQS0 becomes a high level, the circuit nodes N5 and N6 are precharged on the ground potential VSS and an amplifier circuit A1 is inactivated. Further, the DFE circuit 200A is coupled to each of the circuit nodes N5 and N6.

The transistors 215, 216, 222, and 223 constitute a flip-flop circuit F. That is, the transistors 215 and 222 are coupled in series between the power line L1 supplied with the power potential VDD and a circuit node N1, and gate electrodes thereof are coupled in common to drains of the transistors 216 and 223. The circuit node N1 constitutes one input node of the flip-flop circuit F. The transistors 216 and 223 are coupled in series between the power line L1 supplied with the power potential VDD and a circuit node N2, and gate electrodes thereof are coupled in common to drains of the transistors 215 and 222. The circuit node N2 constitutes the other input node of the flip-flop circuit F. Internal write data IDQ0T is output from the drains of the transistors 215 and 222 constituting one output node. Internal write data IDQ0B is output from the drains of the transistors 216 and 223 constituting the other output node. When the internal data strobe signal DQS0 becomes a low level, internal write data IDQ0T/B is precharged on the power potential VDD by the transistors 213 and 214.

The transistor 224 is coupled between the circuit node N1 and a circuit node N3. A gate electrode of the transistor 224 is coupled to the circuit node N5. The circuit node N3 is coupled to the power line L2 supplied with the ground potential VSS via the current control circuit 230 and a transistor 226. A transistor 225 is coupled between the circuit node N2 and a circuit node N4. A gate electrode of the transistor 225 is coupled to the circuit node N6. The circuit node N4 is coupled to the power line L2 supplied with the ground potential VSS via the current control circuit 240 and the transistor 227. With this configuration, the transistors 224 and 225 constitute an amplifier circuit A2 that supplies an operating current to the flip-flop circuit F based on the potentials of the circuit nodes N5 and N6.

The current control circuit 230 is formed of transistors 231, 232, and 234 that are coupled in parallel between the circuit node N3 and the power line L2 supplied with the ground potential VSS. Inversion signals of each of bits DN0, DN1, and DN2 constituting a down-code signal DN are respectively input to gate electrodes of the transistors 231, 232, and 234. The down-code signal DN is a signal in binary form. The bit DN0 is a least significant bit of the down-code signal DN and the transistor 231 input with an inversion signal of the bit DN0 constitutes a least significant transistor. The bit DN2 is a most significant bit of the down-code signal DN and the transistor 234 input with an inversion signal of the bit DN2 constitutes a most significant transistor. Here, when the transistor size of the transistor 231 is set as “1”, the transistor size of the transistor 232 is “2” and the transistor size of the transistor 234 is “4”. Further, the transistor 226 is coupled in parallel to the current control circuit 230. Since the power potential VDD is applied to a gate electrode of the transistor 226 in a fixed manner, the transistor 226 is turned ON regardless of the down-code signal DN.

The current control circuit 240 is formed of transistors 241, 242, and 244 that are coupled in parallel between the circuit node N4 and the power line L2 supplied with the ground potential VSS. Inversion signals of each of bits UP0, UP1, and UP2 constituting an up-code signal UP are respectively input to gate electrodes of the transistors 241, 242, and 244. The up-code signal UP is a signal in binary form. The bit UP0 is a least significant bit of the up-code signal UP and the transistor 241 input with an inversion signal of the bit UP0 constitutes a least significant transistor. The bit UP2 is a most significant bit of the up-code signal UP and the transistor 244 input with an inversion signal of the bit UP2 constitutes a most significant transistor. Here, when the transistor size of the transistor 241 is set as “1”, the transistor size of the transistor 242 is “2” and the transistor size of the transistor 244 is “4”. Further, the transistor 227 is coupled in parallel to the current control circuit 240. Since the power potential VDD is applied to a gate electrode of the transistor 227 in a fixed manner, the transistor 227 is turned ON regardless of the up-code signal UP.

Here, the sizes of the transistor 231 and the transistor 241 are mutually the same. The sizes of the transistor 232 and the transistor 242 are mutually the same. The sizes of the transistor 234 and the transistor 244 are mutually the same. The sizes of the transistor 226 and the transistor 227 are mutually the same.

With such a circuit configuration, the amount of current flowing into the current control circuit 230 according to the down-code signal DN can be adjusted. Similarly, the amount of current flowing into the current control circuit 240 can be adjusted according to the up-code signal UP. Accordingly, when there is an input offset in the data latch circuit 200, by adjusting the amount of current flowing into the current control circuits 230 and 240 using the down-code signal DN and the up-code signal UP, the input offset can be cancelled.

Each of other data latch circuits 201 to 203 constituting the input buffer 20 has a circuit configuration identical to that of the data latch circuit 200 shown in FIG. 3. Mutually different down-code signals DN and up-code signals UP are used for each of the data latch circuits 200 to 203, and thus each input offset in the data latch circuits 200 to 203 is cancelled in each of these circuits.

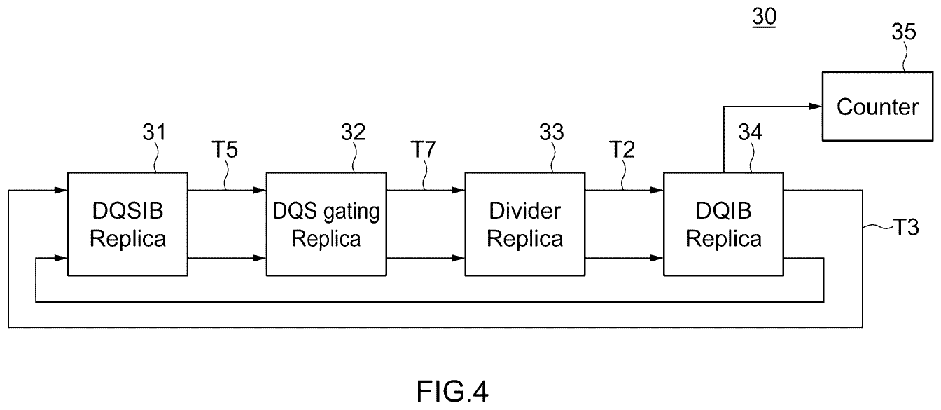

FIG. 4 is a block diagram showing a configuration of a write oscillator circuit 30 included in the data control circuit 16. The write oscillator circuit 30 is a circuit for monitoring the operating speed of the input buffer 20. As shown in FIG. 4, the write oscillator circuit 30 has a configuration in which a DQSIB replica circuit 31, a DQS gating replica circuit 32, a divider replica circuit 33, and a DQIB replica circuit 34 are circularly connected.

The DQSIB replica circuit 31 is a replica circuit of the input buffer 21 shown in FIG. 2. The DQSIB replica circuit 31 receives a timing signal T3 and outputs a timing signal T5. The time period from when the timing signal T3 is activated until when the timing signal T5 is activated is designed to be approximately the same as the time period from when the data strobe signals DQST, DQSC are supplied to the data strobe terminals 18, 19 until when the timing signal T4 is activated.

The DQS gating replica circuit 32 is a replica circuit of the gating circuit 22 shown in FIG. 2. The DQS gating replica circuit 32 receives the timing signal T5 and outputs the timing signal T7. The time period from when the timing signal T5 is activated until when the timing signal T7 is activated is designed to be approximately the same as the time period from when the timing signal T4 is activated until when the timing signal T6 is activated.

The divider replica circuit 33 is a replica circuit of the dividing circuit 23 shown in FIG. 2. The divider replica circuit 33 receives the timing signal T7 and outputs the timing signal T2. The time period from when the timing signal T7 is activated until when the timing signal T2 is activated is designed to be approximately the same as the time period from when the timing signal T6 is activated until when the internal data strobe signal DQS0 is activated.

The DQIB replica circuit 34 is a replica circuit of the data latch circuit 200 shown in FIG. 2. The DQIB replica circuit 34 receives a timing signal T2 and outputs a timing signal T3. The time period from when the timing signal T2 is activated until when the timing signal T3 is activated is designed to be approximately the same as the time period from when the internal data strobe signal DQS0 is activated until when the write data IDQ0 is latched.

The number of gate stages of the circularly connected circuits 31 to 34 is an odd number. Therefore, when the write oscillator circuit 30 is activated, each timing signal oscillates. The write oscillator circuit 30 further includes a counter circuit 35. The counter circuit 35 performs a count-up operation every time the timing signal T3 is activated. As a result, the count value of the counter circuit 35 obtained when the write oscillator circuit 30 is activated for a predetermined period is inversely proportional to the oscillation period of the circularly connected circuits 31 to 34. Because these circuits 31 to 34 are replica circuits of the input buffer 21, the gating circuit 22, the dividing circuit 23, and the data latch circuit 200 shown in FIG. 2, respectively, it is possible to measure a time period from when the data strobe signals DQST and DQSC are actually input from outside until the write data DQ is actually latched in the data latch circuit 200 by referring to the count value of the counter circuit 35.

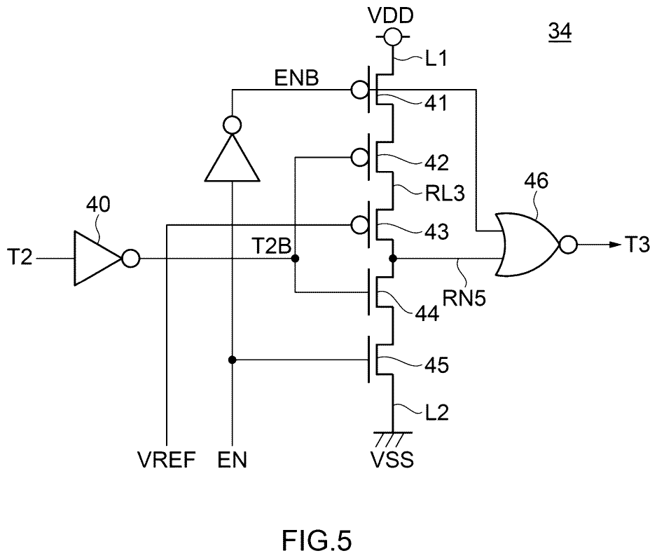

FIG. 5 is a circuit diagram of the DQIB replica circuit 34. As shown in FIG. 5, the DQIB replica circuit 34 includes an inverter 40 that receives a timing signal T2 and generates an inverted signal T2B, transistors 41-45 connected in series in this order between the power line L1 supplied with the power potential VDD and the power line L2 supplied with the ground potential VSS, and a NOR gate circuit 46. The inverter 40 is a replica circuit of the inverter M300 shown in FIG. 3. The transistors 41-43 are P-channel MOS transistors. The transistors 44 and 45 are N-channel MOS transistors.

An enable signal EN is supplied to the gate electrode of transistor 45. An inverted signal ENB of the enable signal EN is supplied to the gate electrode of transistor 41. The enable signal EN is a signal for activating the DQIB replica circuit 34. When the enable signal EN is at a low level, the DQIB replica circuit 34 is inactivated and the oscillation of the write oscillator circuit 30 stops. An inverted signal T2B is commonly supplied to the gate electrodes of transistors 42 and 44. The reference potential VREF is supplied to the gate electrode of transistor 43. The reference potential VREF may be the same as the reference potential VREF supplied to the gate electrode of transistor 212 shown in FIG. 2.

Transistor 42 is a replica circuit of transistor 210 shown in FIG. 3. Therefore, the circuit node RL3, which is the drain of transistor 42, is a replica of the common source line L3. Transistor 43 is a replica circuit of transistor 211 shown in FIG. 3. Therefore, the circuit node RN5, which is the drain of transistor 43, is a replica of the circuit node N5.

One input node of the NOR gate circuit 46 is connected to the circuit node RN5. The other input node of the NOR gate circuit 46 is supplied with an inverted signal ENB of the enable signal EN. As a result, the NOR gate circuit 46 is activated when the enable signal EN is at a high level, and outputs a timing signal T3 that is an inverted version of the level of the circuit node RN5.

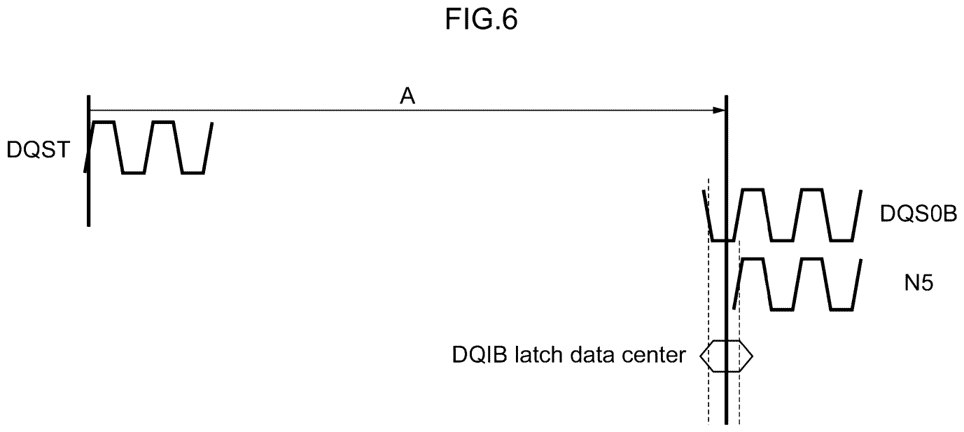

FIG. 6 is a timing diagram for explaining the function of the write oscillator circuit 30. In the example shown in FIG. 6, the timing after the data strobe signal DQST input from the outside rises and the period A has elapsed is the timing of the center of the write data DQ latched by the data latch circuit 200. Here, the timing when the inverted signal DQS0B of the internal data strobe signal DQS0 falls to a low level is slightly earlier than the center of the write data DQ, and the timing when the level of the circuit node N5 is determined is slightly later than the center of the write data DQ. Such a timing difference between the inverted signal DQS0B and the circuit node N5 is reproduced in the DQIB replica circuit 34 by inserting a transistor 43 that receives the reference potential VREF between transistors 42 and 44 that receive a timing signal T2B, which is a replica of the inverted signal DQS0B. As a result, the timing signal T3 is approximately synchronized with the timing at which the write data DQ is latched into the data latch circuit 200, making it possible for the write oscillator circuit 30 to more accurately reproduce the period from when the data strobe signal DQST rises to when the write data DQ is actually latched into the data latch circuit 200.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
an input buffer circuit; and
a first replica circuit configured to replicate the input buffer circuit,
wherein the input buffer circuit includes:
a first transistor coupled between a first power line supplied with a first power potential and a common source line and having a control electrode supplied with a first timing signal;
a second transistor coupled between the common source line and a first circuit node and having a control electrode supplied with an input signal;
a third transistor coupled between the common source line and a second circuit node and having a control electrode supplied with a reference potential; and
an amplifier circuit having a pair of first and second input nodes, the first input node being coupled to the first circuit node, the second input node being coupled to the second circuit node,
wherein the first replica circuit includes fourth and fifth transistors coupled in series between the first power line and a third circuit node,
wherein the fourth transistor has a control electrode supplied with a second timing signal, and
wherein the fifth transistor has a control electrode supplied with the reference potential.

2. The apparatus of claim 1, wherein each of the first, second, third, fourth, and fifth transistors has a first conductivity type.

3. The apparatus of claim 2,
wherein the first replica circuit further includes a sixth transistor coupled between the third circuit node and a second power line supplied with a second power potential different from the first power potential, and
wherein the sixth transistor has a control electrode supplied with the second timing signal.

4. The apparatus of claim 3, wherein the sixth transistor has a second conductivity type different from the first conductivity type.

5. The apparatus of claim 4, wherein the fifth transistor is coupled between the fourth transistor and the sixth transistor.

6. The apparatus of claim 5, wherein the third circuit node is a connection node between the fifth transistor and the sixth transistor.

7. The apparatus of claim 6,
wherein the first replica circuit further includes a seventh transistor having the first conductivity type and coupled between the first power line and the fourth transistor and an eighth transistor having the second conductivity type and coupled between the sixth transistor and the second power line,
wherein the eighth transistor has a control electrode supplied with an enable signal, and
wherein the seventh transistor has a control electrode supplied with an inverted signal of the enable signal.

8. The apparatus of claim 7, wherein the first replica circuit further includes a gate circuit configured to generate a third timing signal based on a potential of the third circuit node when the enable signal is activated.

9. The apparatus of claim 8, further comprising:
a timing signal generator configured to generate the first timing signal based on an original timing signal supplied to an external terminal electrode; and
a second replica circuit configured to replicate the timing signal generator,
wherein the second replica circuit is configured to generate the second timing signal based on the third timing signal.

10. The apparatus of claim 9, further comprising a counter circuit configured to update a count value each time the third timing signal is activated.

11. The apparatus of claim 6, wherein the amplifier circuit includes a seventh transistor having a control electrode as the first input node and an eighth transistor having a control electrode as the second input node.

12. An apparatus comprising:
a timing signal generator configured to generate a first timing signal based on an original timing signal supplied from outside;
a first input buffer circuit configured to latch an input data supplied from outside responsive to the first timing signal;
a first replica circuit configured to generate a second timing signal based on a third timing signal; and
a second replica circuit configured to generate the third timing signal based on the second timing signal,
wherein the first input buffer circuit includes:
first and second transistors coupled in series between a first power line supplied with a first power potential and a first circuit node; and
an amplifier circuit coupled in series between the first power line and a second power line supplied with a second power potential different from the first power potential and having a first input node coupled to the first circuit node,
wherein the first transistor is configured to be controlled by the first timing signal,
wherein the second transistor is configured to be controlled by the input data,
wherein the second replica circuit includes third, fourth, and fifth transistors coupled in series between the first and second power lines,
wherein each of the first, second, third, and fourth transistors has a first conductivity type,
wherein the fifth transistor has a second conductivity type different from the first conductivity type,
wherein the third and fifth transistors are configured to be controlled by the second timing signal, and
wherein the fourth transistor is configured to be controlled by a reference potential.

13. The apparatus of claim 12,
wherein a potential of the input data is changed in a range of a first potential to a second potential, and
wherein the reference potential is higher than the first potential and lower than the second potential.

14. The apparatus of claim 13,
wherein the first input buffer circuit further includes a sixth transistor having the first conductivity type,
wherein the first and sixth transistors are coupled in series between the first power line and a second circuit node,
wherein the amplifier circuit further has a second input node coupled to the second circuit node, and
wherein the sixth transistor is configured to be controlled by the reference potential.

15. The apparatus of claim 13, further comprising a counter circuit configured to update a count value each time the third timing signal is activated.

16. The apparatus of claim 13,
wherein the timing signal generator includes a second input buffer circuit configured to generate a fourth timing signal based on the original timing signal, and
wherein the first replica circuit includes a replica buffer circuit of the second input buffer circuit configured to generate a fifth timing signal based on the third timing signal.

17. The apparatus of claim 16,
wherein the timing signal generator further includes a driver circuit configured to generate a sixth timing signal based on the fourth timing signal, and
wherein the first replica circuit further includes a replica gating circuit of the driver circuit configured to generate a seventh timing signal based on the fifth timing signal.

18. The apparatus of claim 17,
wherein the timing signal generator further includes a divider circuit configured to generate the first timing signal based on the sixth timing signal, and
wherein the first replica circuit further includes a replica divider circuit of the divider circuit configured to generate the second timing signal based on the seventh timing signal.

19. An apparatus comprising:
a differential amplifier circuit having a pair of first and second input transistors, the first input transistor having a control electrode supplied with an input signal, the second input transistor having a control electrode supplied with a reference potential; and
a replica circuit having first, second, and third replica transistors coupled in series,
wherein the differential amplifier circuit is configured to be activated responsive to a first timing signal,
wherein each of the first and second input transistors and the first and second replica transistors has a first conductivity type,
wherein the third replica transistor has a second conductivity type different from the first conductivity type,
wherein each of the first and third replica transistors has a control electrode supplied with the second timing signal, and
wherein the second replica transistor has a control electrode supplied with the reference potential.

20. The apparatus of claim 19, further comprising a gate circuit configured to generate a third timing signal based on a potential of a circuit node between the second and third replica transistors,
wherein the replica circuit and the gate circuit are configured to be activated responsive to an enable signal.
